(19) United States
(12) Patent Application Publication
(10) Pub. No.: US 2012/0217475 A1
(43) Pub. Date: Aug. 30, 2012

(54) Optoelectronic Devices Including Compound Valence-Band Quantum Well Structures

(76) Inventor: Richard P. Leavitt, Silver Spring, MD (US)

(21) Appl. No.: 13/035,231

(22) Filed: Feb. 25, 2011

(51) Int. Cl. H01L 29/06

(52) U.S. Cl. 257/14; 257/E29.005

(57) ABSTRACT

Semiconductor optoelectronic devices based on type-II band alignments comprising a compound valence-band quantum well structure, known as an H-layer, are disclosed. The use of the H-layer structure allows simultaneous optimization of optical properties of the semiconductor structures as well as lattice matching of the various layers of the device. The use of H-layer valence-band quantum wells enables improvements to several optical device applications including semiconductor lasers, optical modulators, photon detectors and the like.

### GOVERNMENT CONTRACT

This invention was made with United States government support under Contract Number HQ006-10-C-7355 awarded by the U.S. Missile Defense Agency. The United States government has certain rights in this invention.

### FIELD OF THE INVENTION

The present invention relates to optoelectronic devices, and more particularly relates to mid-infrared optoelectronic devices based on type-II band alignments having a compound valence-band quantum well structure.

### BACKGROUND INFORMATION

Optoelectronic devices based on the III-V family of compound semiconductors have assumed an increasingly important role in a wide variety of applications. Such devices include various types of semiconductor lasers, optical modulators, photon detectors and the like. The wavelengths of these optoelectronic devices have reached into the mid-infrared spectral region with the increasing maturity of “6.1-Å” materials including InAs, GaSb, AlSb and their alloys.

The heterojunctions involved in optoelectronic device structures that use the 6.1-Å materials often have type-II or broken-gap band alignments, in which electrons are localized in one set of material layers and holes are localized in another set of material layers. A feature of type-II-based semiconductor optoelectronic devices is that some of the semiconductor layers in such devices are not lattice-matched to the substrates used. These layers are usually grown by a technique such as molecular beam epitaxy. The lattice mismatches of individual layers relative to the substrate introduces another challenge in the design of such devices, namely, the necessity of strain balancing the various layers of such devices.

In the type-II material systems typically used in optoelectronic device applications, the strain balancing problem is complicated by the fact that adjacent materials typically share neither a common cation nor a common anion. Thus, the interfaces separating adjacent materials can have a variety of different types of structures depending on whether a layer of cations, anions, or a mixture of cations and anions terminates the first of a pair of materials. The structures of these interfaces can possibly be altered by using techniques such as deposition of additional group III elements or soaks with group V species in attempts to achieve overall strain balancing of the epitaxial structures. However, the material quality of the epitaxial films is often compromised by these treatments.

It is known to use materials having type-II band alignments in mid-infrared photon detectors. For example, InAs has been used as the conduction-band quantum well and either the alloy (In,Ga)Sb or GaSb have been used as the valence-band quantum well. For these types of devices, the key quantity of interest is the optical matrix element between the highest energy valence-band state of the system and the lowest energy conduction-band state of the system.

Attempts have been made to improve the performance of type-II infrared detectors by introducing a specialized type of active region based on a “W” structure which, rather than using a simple pair of semiconductor layers as the basic absorbing unit, uses a sequence of four layers: InAs; (In,Ga)Sb; InAs; and (In,Al,Ga)Sb. The first three of these layers comprise the W structure and the fourth is a barrier layer that separates adjacent repeats of the basic unit. However, the use of the (In,Al,Ga)Sb, or simply AlSb, inhibits transport of photogenerated carriers through the active region of the structure and thus is detrimental to good detector performance.

A number of different types of electron- and hole-blocking layers have been used to improve the dark current characteristics of type-II superlattice detectors. For example, nBn structures with blocking layers based on InAs/GaSb type-II strained layer superlattices have been proposed.

Another family of optoelectronic devices that can be extended into the mid-infrared spectral region is the optical modulator based on the principle of the Stark shift, which is a shift in the fundamental absorption edge of a quantum well system with application of an electric field. Depending on the difference in energy between the fundamental absorption edge and the photon energy, such a mechanism can produce a change in either the real or the imaginary component of the medium's index of refraction. Consequently, a device based on this mechanism can serve either as an intensity modulator or a phase modulator.

Another type of optoelectronic device that utilizes type-II semiconductor materials is the interband cascade laser. Certain variants of the interband cascade laser utilize the W structure in the active region of the device. The W structure has also been used in type-II-based conventional (non-cascaded) diode lasers, and in optically-pumped type-II lasers.

The performance of semiconductor optoelectronic devices based on type-II material systems is generally a compromise between optimizing the relevant optical properties of the structure and strain balancing the structure. It would be desirable to produce a new type of semiconductor structure for use in the active regions of such devices that would allow, simultaneously and independently, the optimization of the relevant optical properties and the strain balancing of the epitaxial structure. Such a structure would achieve significant improvements in the performance of many different types of optoelectronic devices.

The present invention has been developed in view of the foregoing and to remedy other deficiencies of the prior art.

### SUMMARY OF THE INVENTION

The present invention provides semiconductor optoelectronic devices based on type-II band alignments comprising a compound valence-band quantum well structure, known as an “H-layer”, that optimizes device performance and material quality. The use of the H-layer structure allows simultaneous optimization of relevant optical properties of the semiconductor structures in which the H-layer structure is contained as well as lattice matching of the device structure to the selected substrate. The unique properties of the H-layer valence-band quantum well enable significant improvements in many optical device applications.

One embodiment of the invention provides a type-II quantum well structure containing the H-layer valence-band quantum well permitting strain balancing of the structure to an appropriate substrate. In another embodiment of the invention, an infrared detector that utilizes the type-II quantum well structure containing the H-layer valence-band quantum well is provided. The infrared detector may optionally include blocking layers. In a further embodiment, an infrared optical modulator that utilizes the type-II quantum well structure containing the H-layer valence-band quantum well is provided. In another embodiment, an interband cascade laser that utilizes the type-II quantum well structure containing the H-layer valence-band quantum well is provided. In a further embodiment, a W diode laser that utilizes the type-II quantum well structure containing the H-layer valence-band quantum well is provided. In another embodiment, an optically pumped laser that utilizes the type-II quantum well structure containing the H-layer valence-band quantum well is provided.

An aspect of the present invention is to provide a type-II optoelectronic device including one or more compound valence-band quantum well structures. The compound valence-band quantum well structures comprise a central layer and a pair of shoulder layers located on opposite sides of the central layer, wherein each shoulder layer has a valence-band-edge energy larger than a valence-band-edge energy of the central layer.

Another aspect of the present invention is to provide a type-II optoelectronic device including one or more compound valence-band quantum well structures. The compound valence-band quantum well structures comprise a central layer and a pair of shoulder layers located on opposite sides of the central layer, wherein at least one of the shoulder layers reduces strain caused by a lattice mismatch between a substrate of the device and other layers of the device.

These and other aspects of the present invention will be more apparent from the following description.

### BRIEF DESCRIPTION OF THE DRAWINGS

FIGS. 1A and 1B are energy-band diagrams depicting different types of band alignments encountered in semiconductor heterojunctions. FIG. 1A illustrates a type-I band alignment. FIG. 1B illustrates a type-II band alignment.

FIG. 2 is an energy-band diagram illustrating the splitting of the valence band arising from strain and showing confinement of electron and hole wave functions in two different layers in type-II material systems.

FIG. 3 is an energy-band diagram corresponding to an H-layer valence-band quantum well in accordance with an embodiment of the present invention.

FIG. 4 is a partially schematic cross-sectional view of an H-layer valence-band quantum well structure with a conduction-band quantum well on either end in accordance with an embodiment of the present invention.

FIG. 5 is a partially schematic cross-sectional view of an epitaxial structure grown on a substrate with contact layers on either side of a type-II quantum well structure containing several H-layer valence-band quantum wells in accordance with an embodiment of the present invention. The epitaxial structure represents either a type-II infrared detector or a type-II infrared optical modulator.

FIG. 6 is a partially schematic cross-sectional view of a type-II infrared detector structure containing H-layer valence-band quantum wells and blocking layers in accordance with an embodiment of the present invention.

FIG. 7 is a partially schematic cross-sectional view of a type-II interband cascade laser grown on a substrate with contact layers, cladding layers, and a gain region containing multiple periods of appropriate injection regions and W-type active regions comprising two conduction-band quantum wells on either side of the H-layer valence-band quantum wells in accordance with an embodiment of the present invention.

FIG. 8 is a partially schematic cross-sectional view of the gain region of either a type-II diode laser or an optically-pumped type-II laser containing multiple periods of appropriate barrier layers and W-type active regions comprising two conduction-band quantum wells on either side of the H-layer valence-band quantum wells in accordance with an embodiment of the present invention.

FIG. 9 shows a measured x-ray diffraction spectrum of a type-II infrared detector structure containing H-layer valence-band quantum wells in accordance with an embodiment of the present invention.

FIG. 10 shows an atomic-force-microscope image of a portion of a type-II infrared detector structure containing H-layer valence-band quantum wells in accordance with an embodiment of the present invention.

FIG. 11 shows the results of measurements of the absolute value of dark-current density plotted as a function of device bias for four detector diodes that were fabricated from a type-II infrared detector structure containing H-layer valence-band quantum wells in accordance with an embodiment of the present invention.

FIG. 12 shows the results of measurements of the external quantum efficiency as a function of wavelength for a diode that was fabricated from a type-II infrared detector structure containing H-layer valence-band quantum wells in accordance with an embodiment of the present invention.

FIG. 13 shows the results of calculating the detectivity from measured dark-current density and external quantum efficiency as a function of wavelength for a diode fabricated from a type-II infrared detector structure containing H-layer valence-band quantum wells in accordance with an embodiment of the present invention.

### DETAILED DESCRIPTION

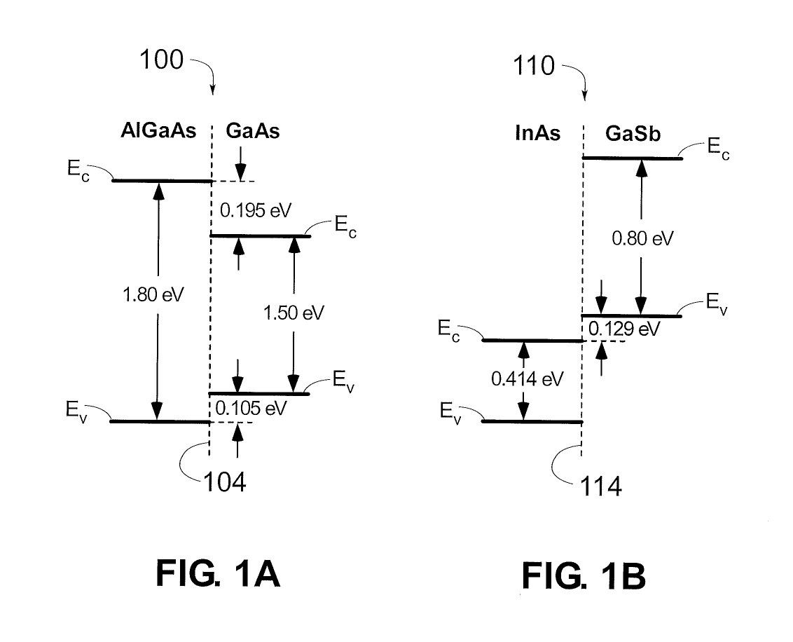

FIGS. 1A and 1B schematically illustrate two of the possible band alignments achievable with III-V semiconductor heterojunctions. FIG. 1A shows, by way of example, a heterostructure 100 comprised of adjacent AlGaAs and GaAs layers, each of which is characterized by specific values of a conduction-band-edge energy E_{c} and a valence-band-edge energy Eᵥ with a heterointerface 104 between the adjacent layers. The band alignment shown in FIG. 1A, in which one of the layers has both the larger value of Eᵥ and the smaller value of E_{c}, is referred to as a type-I or straddling band alignment. In type-I alignment, both electrons and holes are confined to the same semiconductor layer, i.e., the layer that has both the largest value of Eᵥ and the smallest value of E_{c}. This material is the one with the lower band gap E_{g} of the two materials (defined by E_{g}=E_{c}−Eᵥ).

FIG. 1B shows by way of example a different heterostructure 110 comprised of adjacent InAs and GaSb layers, with a heterointerface 114 between the adjacent layers, in which the value of the valence-band-edge energy Eᵥ for one material (GaSb in this example) is larger than the value of the conduction-band-edge energy E_{c} for the other material (InAs in this example). The band alignment typified by this example is referred to as type-II or broken-gap band alignment. In type-II alignment, electrons are confined to one layer, i.e., the one with the smaller value of E_{c}, and the holes are confined to the other layer, i.e., the one with the larger value of Eᵥ.

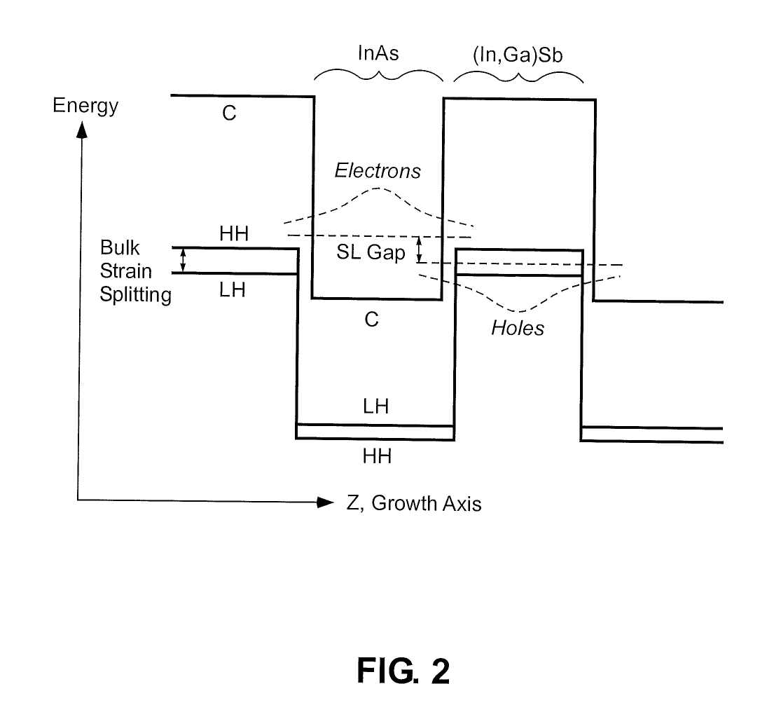

FIG. 2 schematically illustrates the electron and hole confinement in separate layers of a structure having type-II band alignments, which in this example are InAs and (In,Ga)Sb, respectively. FIG. 2 also shows the splittings of the valence bands in both materials that arise from the presence of strain in these materials. The split valence bands are referred to as heavy-hole (HH) and light-hole (LH) bands. The conduction band C remains unsplit. The effective energy gap of the type-II superlattice, referred to as the superlattice gap and labeled “SL Gap” in FIG. 2, is determined by the confinement energies of electrons in the material with the lower value of E_{c}, in this case, InAs, and of holes in the material with the higher value of Eᵥ, in this case, (In,Ga)Sb.

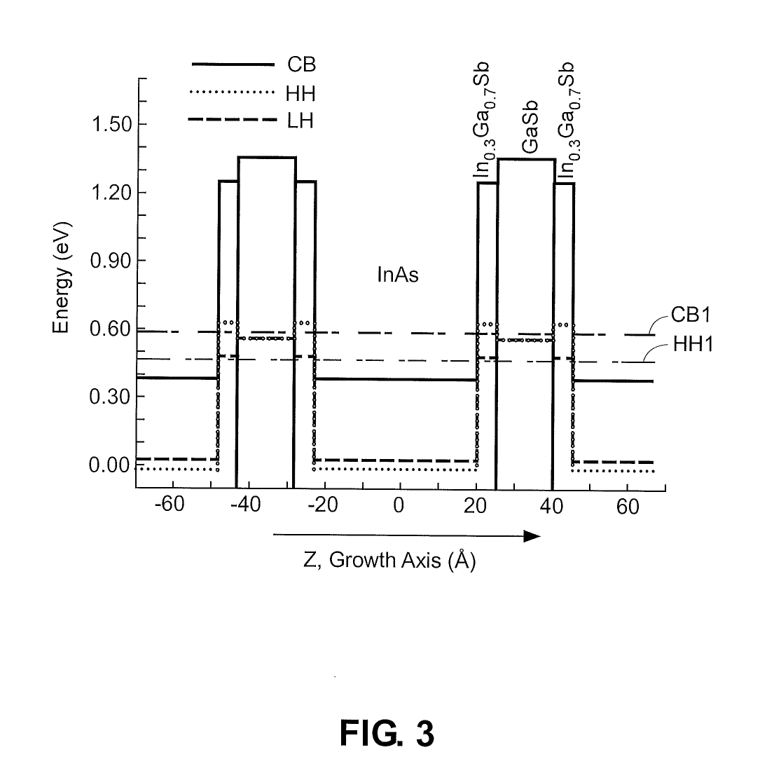

FIG. 3 schematically illustrates, by way of example, an energy-band diagram for an H-layer valence-band quantum well structure in accordance with an embodiment of the present invention. The H-layer valence-band quantum well consists of a central layer comprising GaSb and two adjacent shoulder layers comprising In_{0.3}Ga_{0.7}Sb. The conduction-band quantum wells that separate adjacent H-layer structures comprise InAs. The conduction-band CB, heavy-hole HH band, and light-hole LH band edges are also shown. In the H-layer portions of FIG. 3, the valence-band structure HH and LH resembles the letter “H”. The highest energy valence-band state of the system is labeled HH1, and the lowest-energy conduction-band state of the system is labeled CB1. In FIG. 3, the HH band in each InGaSb layer corresponds to the valence-band-edge energy Eᵥ for that layer, and the overlapping HH and LH bands in the GaAs layer correspond to the valence-band-edge energy Eᵥ for that layer. Appropriate thicknesses for the layers comprising the structure typified by FIG. 3 depend on the types of materials used and the particular device application, but are typically on the order of one to several tens of monolayers (ML). In the example of FIG. 3, the thickness of a single ML is about 3 Å.

The use of the H-layer structure allows simultaneous optimization of the relevant optical properties of an optoelectronic device in which the H-layer structure is contained, as well as lattice matching of that device to the substrate upon which it is grown without the necessity of interface treatments referred to earlier. In so doing, the present invention simultaneously solves two different problems that had previously been considered to be independent of one another and that also previously entailed compromises to device performance.

To illustrate the benefits of the H-layer structure in terms of lattice matching, we consider the design of an infrared detector with a cutoff wavelength of 10 μm. Using a conventional design based on an epitaxial structure consisting of sequential layers of InAs and GaSb, grown on a GaSb substrate, a structure comprised of multiple repeats of 45.1 Å of InAs and 27.4 Å of GaSb results in the desired cutoff wavelength. However, because the GaSb layers have the same lattice parameter as the substrate (6.09593 Å) and the InAs layers have a smaller lattice parameter (6.0584 Å), the epitaxial structure is not lattice matched to the GaSb substrate. The mismatch, defined as the relative deviation of the epitaxial structure's in-plane lattice parameter from the substrate's lattice parameter, is calculated as −0.00313, which is large enough to cause dislocations during the structure's growth and thereby degrade its performance. However, an H-layer epitaxial structure can be designed for the same cutoff wavelength that incorporates In_{0.3}Ga_{0.7}Sb shoulder layers that serve as lattice-matching layers. In this case, the structure consists of multiple repeats of 42.12 Å of InAs, 5.24 Å of In_{0.3}Ga_{0.7}Sb, 13.87 Å of GaSb, and another 5.24 Å of In_{0.3}Ga_{0.7}Sb. The GaSb layers still have the same lattice parameters as the substrate (6.09593 Å) and the InAs layers have a smaller lattice parameter (6.0584 Å), but the added In_{0.3}Ga_{0.7}Sb layers have a larger lattice parameter (6.21097) than the substrate. The mismatch of the structure relative to the substrate is zero, and the epitaxial structure is lattice matched to the substrate. Thus, the shoulder layers eliminate the lattice mismatch that would otherwise occur between the substrate and the other layers of the device.

Optoelectronic devices that are based on type-II band alignments rely on a transition between a valence-band state that is localized in one type of material and a conduction-band state that is localized in a different material. Consequently, the optical transition is sensitive to conditions in the vicinity of the interface between the two materials, and the strength of that transition is susceptible to imperfections at the interface. In accordance with the present invention, by freeing the device designer from attempting to alter the interface in order to achieve lattice matching, the H-layer structure improves type-II device performance. Furthermore, since one characteristic of the H-layer structure is the “pulling” of the wave function of the highest-energy hole state toward these interfaces, the optical matrix element between this state and the lowest-energy conduction-band state is made larger, thereby intrinsically improving the performance of a wide variety of optoelectronic devices into which the H-layer valence-band quantum well can be incorporated. In the case of a detector or an optical modulator, improvements in device performance are achieved because the increased optical matrix element results in a larger value of the device's absorption coefficient. In the case of a laser, improvements in device performance are achieved because the increased optical matrix element results in a larger value of the device's gain.

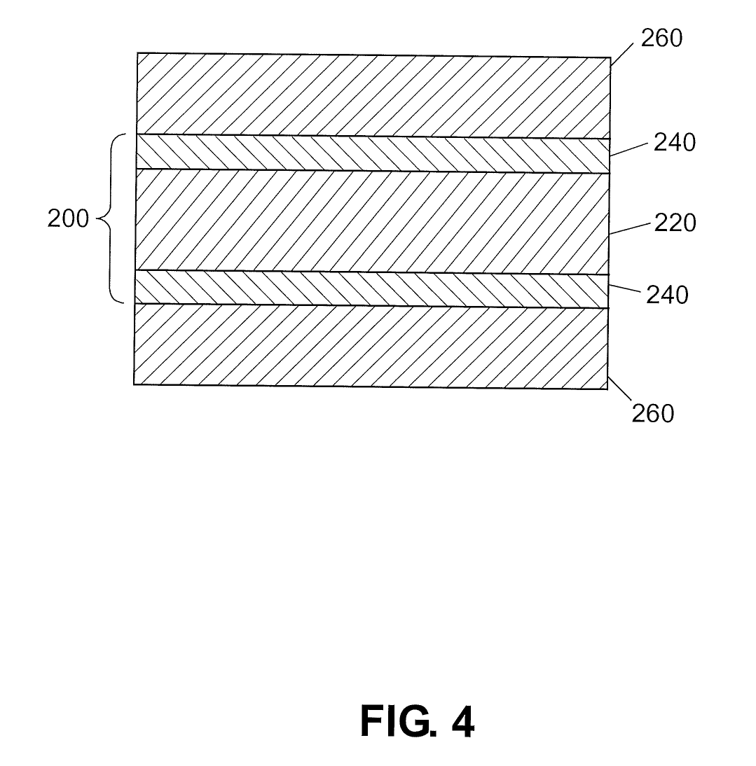

FIG. 4 schematically illustrates a cross section of an H-layer valence-band quantum well structure in accordance with an embodiment of the present invention. The H-layer valence-band quantum well 200 comprises a central layer 220 with shoulder layers 240 on either side. The shoulder layer can be any layer that serves to aid in strain-balancing the overall quantum well structure and whose valence-band-edge energy Eᵥ is larger than the value of Eᵥ for the central layer. Adjacent to the H-layer valence-band quantum well are conduction-band quantum well layers 260. The optical transition takes place between a valence-band state in the H-layer structure 200 and a conduction-band state in the conduction-band quantum well layer 260. The layers 220, 240 and 260 are coextensive with each other. It is to be understood that the various layered structures illustrated in the figures are not drawn to scale.

The central layer 220 may be made of GaSb, InₓGa₁₋ₓSb, InₓGa₁₋ₓAs_{y}Sb_{1-y} and the like having a typical thickness of from about 15 to about 100 Å. The shoulder layer 240 may be made of InₓGa₁₋ₓSb, InₓGa₁₋ₓAs_{y}Sb_{1-y} and the like having a typical thickness of from about 2 to about 15 Å. The conduction-band quantum well layers 260 may be made of InAs, InSbₓAs₁₋ₓ and the like having a typical thickness of from about 20 to about 100 Å.

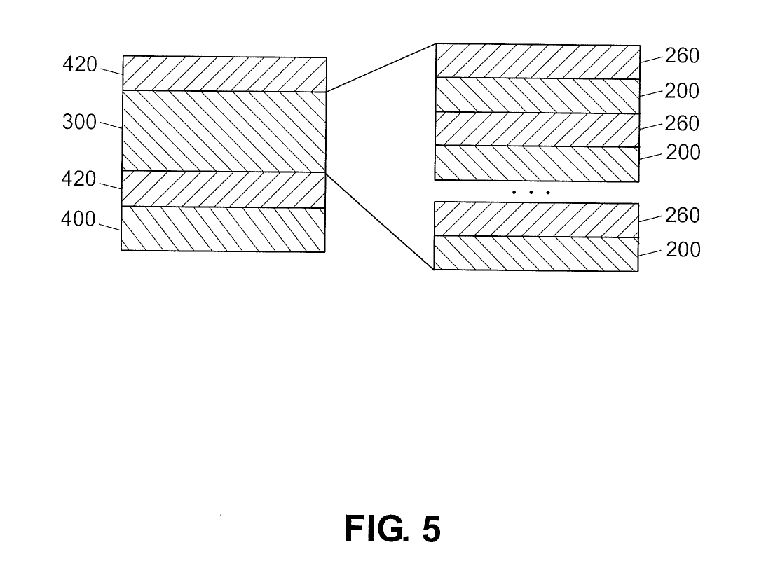

FIG. 5 schematically illustrates a cross section of an epitaxial structure grown on a substrate 400 comprising contact layers 420 on either side of a type-II quantum well structure 300, which in turn contains multiple conduction-band quantum well layers 260 and multiple H-layer valence-band quantum wells 200. The number of H-layer valence-band quantum well layers 200 and conduction-band quantum well layers 260 in the structure 300 may each range from 1 to 1,000 or more, typically from 30 to 800. The substrate 400 may be made of GaSb, InAs and the like having a typical thickness of from about 350 to about 700 microns. The contact layers 420 may be made of layers of one or more of gold, titanium, tin, platinum, germanium and the like having a typical thickness of from about 300 to about 5,000 Å. FIG. 5 corresponds to the structure of either a type-II infrared detector or a type-II infrared optical modulator based on the H-layer structure.

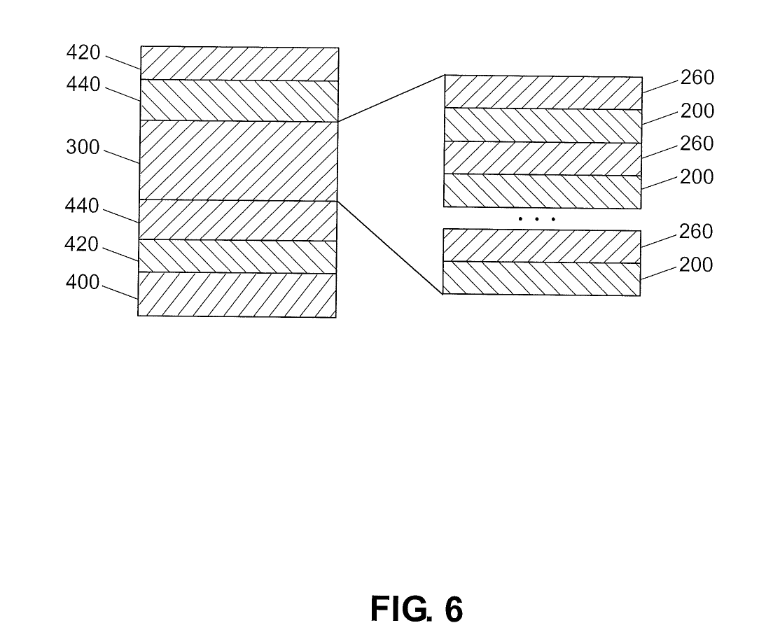

FIG. 6 schematically illustrates a cross section of an epitaxial structure suitable for a type-II infrared detector in accordance with an embodiment of the present invention that incorporates electron- and hole-blocking layers 440, but which is otherwise similar to the embodiment shown in FIG. 5. The blocking layers 440 may be made of combinations of InAs, GaSb, AlSb and the like having a typical thickness of from about 1,000 to about 5,000 Å.

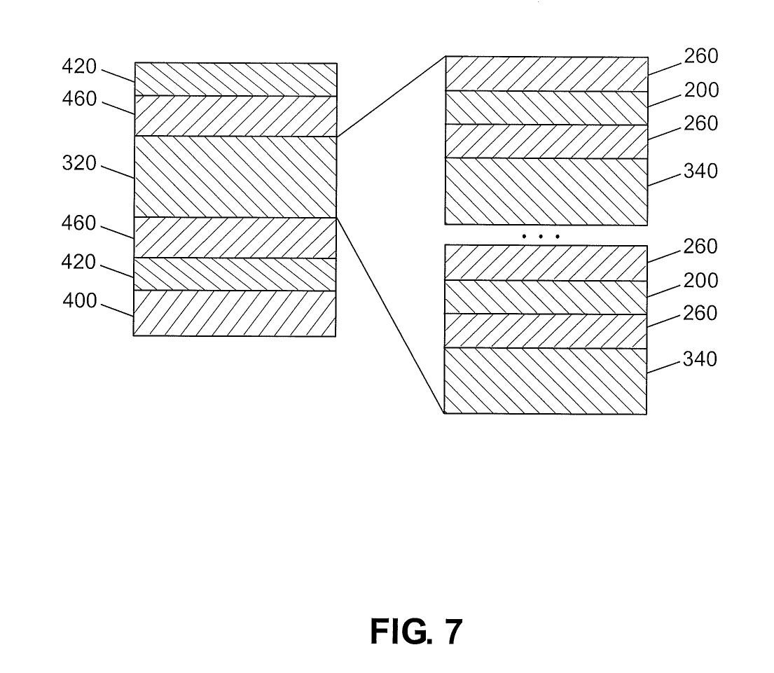

FIG. 7 schematically illustrates a cross section of an epitaxial structure suitable for a type-II interband cascade laser in accordance with an embodiment of the present invention grown on a substrate 400 and comprising contact layers 420 and cladding layers 460 on either side of a type-II gain region 320, which in turn contains one or more repeats of a sequence of layers consisting of a conduction-band quantum well layer 260, H-layer valence-band quantum wells 200, another conduction-band quantum well layer 260, and an injection region layer 340. The cladding layers 460 may be made of combinations of InAs, AlSb, GaSb and the like having a typical combined thickness of from about 5,000 to about 50,000 Å. The injection region layers 340 may be made of combinations of InAs, AlSb, GaSb and the like having a typical thickness of from about 150 to about 600 Å.

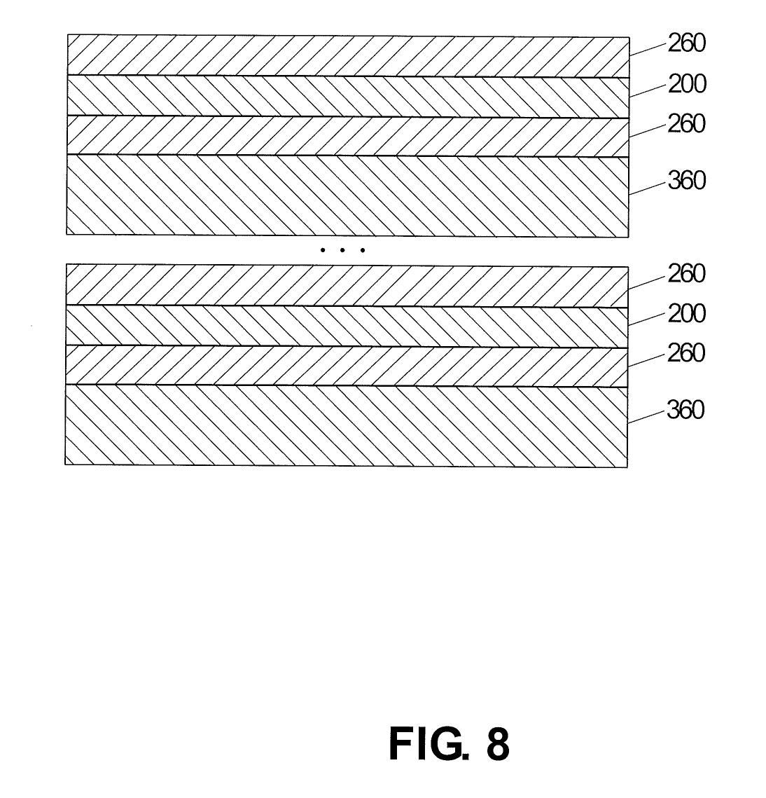

FIG. 8 schematically illustrates a cross section of an epitaxial structure comprising the gain region of either a type-II diode laser or an optically pumped type-II laser and including one or more repeats of a sequence of layers comprising a conduction-band quantum well layer 260, H-layer valence-band quantum wells 200, another conduction-band quantum well layer 260, and a barrier layer 360. The barrier layers 360 may be made of AlSb, AlₓGa₁₋ₓSb, AlₓGa₁₋ₓAs_{y}Sb_{1-y} and the like having a typical thickness of from about 20 to about 100 Å. The gain region shown in FIG. 8 may be incorporated into a type-II diode laser device in the same manner that the gain region 320 shown in FIG. 7 is incorporated into a device including a substrate 400, contact layers 420 and cladding layers 460. Furthermore, the gain region shown in FIG. 8 may be incorporated into an optically pumped type-II laser device in a similar manner as the gain region shown in FIG. 7 is incorporated into a device including a substrate 400 and cladding layers 460, but without the necessity of providing contact layers 420.

Table 1 shows the results of calculations for a type-II infrared detector structure in accordance with an embodiment of the present invention.

TABLE 1
Comparison of Calculated Quantities Pertinent to the Performance
of type-II Superlattice Detectors with ~10-μm Cutoff Wavelengths

| | Conventional | H-Layer VB |
|---|---|---|
| | 15 ML InAs/ | 14 ML InAs/ |
| Quantity | 9 ML GaSb | 8 ML (X)Sb |
| λ_{c} (μm) | 9.99 | 10.10 |
| \|M_{HH1-CB1}\|² | 6.13 | 7.51 |
| (eV²Å²) | | |
| αᵣₑₗ (eV²Å) | 0.0845 | 0.1123 |
| CB MB | 82.0 | 92.6 |
| width (meV) | | |
| HH MB | 0.010 | 0.023 |
| width (meV) | | |
| LH MB | 56.4 | 59.5 |
| width (meV) | | |

Table 1 compares calculated quantities for a conventional type-II detector made with InAs CB quantum wells and GaSb VB quantum wells with the corresponding calculated quantities for a type-II infrared detector with the same calculated cutoff wavelength (λ_{c}˜10 μm) that uses the H-layer valence-band quantum well of the present invention. The other quantities shown in the table are the square of the magnitude of the matrix element, M_{HH1-CB1}, between the highest energy heavy-hole state HH1 and the lowest energy conduction-band state, CB1; the relative absorption coefficient, αᵣₑₗ; and the miniband widths of the lowest energy conduction miniband and the highest energy heavy-hole and light-hole minibands. The calculations show that the value of |M_{HH1-CB1}|² for the H-layer-based structure is improved by 22.5% over the value calculated for the conventional type-II structure; the value of αᵣₑₗ is improved by 33%; and the values of the CB, HH and LH miniband widths are improved by 13%, 130% and 5.5%, respectively.

The H-layer structure used for the calculations in Table 1 consists of 14 mL of InAs and 8 mL of combined In_{0.3}Ga_{0.7}Sb and GaSb forming the H-layer valence-band quantum well. The conventional type-II detector consists of 15 mL of InAs and 9 mL of GaSb. The improvement in the calculated value of |M_{HH1-CB1}|² is attributed to the increased overlap between the electron and hole wave functions arising as a result of the valence-band structure of the H-layer valence-band quantum well. The improvement in the calculated value of αᵣₑₗ is attributed both to the increase in |M_{HH1-CB1}|² and also to the fact that the thickness of a single period of the H layer structure is smaller than that of the conventional structure (αᵣₑₗ is proportional to |M_{HH1-CB1}|² divided by the period thickness). This smaller period thickness also increases the overlap between wave functions corresponding to adjacent periods and is largely responsible for the improved miniband widths in the H-layer structure, which in turn improves carrier transport in the structure, a critical factor in detector performance.

The improvements shown in Table 1 for a type-II infrared detector based on the H-layer valence-band quantum well structure apply as well to the other optoelectronic devices that are embodiments of the instant invention. For example, the absorption coefficient plays a role in the performance of optical modulators that is similar to its role in type-II infrared detectors. Consequently, concomitant improvements in the performance of optical intensity and phase modulators can be achieved. Furthermore, the square of the magnitude of the optical matrix element |M_{HH1-CB1}|² appears in the calculation of the gain of a type-II laser active region. Therefore, the above-cited improvement in this matrix element translates directly into improved performance of various type-II based infrared lasers including interband cascade lasers, diode lasers, and optically pumped lasers.

The following example is intended to illustrate various aspects of the invention, and is not intended to limit the scope of the invention.

### Example

To confirm the performance of the H-layer valence-band quantum well, molecular beam epitaxy was used to grow a detector structure using a structure similar to that shown in FIG. 5. The substrate is n-type GaSb. The bottom electrical contact layer consists of two portions, the first of which has uniform n-type carrier concentration of about 1×10¹⁸ cm⁻³ and the second of which has n-type carrier concentration graded from about 1×10¹⁸ cm⁻³ to about 5×10¹⁵ cm⁻³. The top electrical contact layer also consists of two portions, the first of which has p-type carrier concentration graded from about 5×10¹⁵ cm⁻³ to about 1×10¹⁸ cm⁻³ and the second of which has uniform p-type concentration of about 3×10¹⁸ cm⁻³. The type-II quantum well absorbing region is a type-II superlattice consisting of 451 repeats of 42.12 Å of InAs (which serves as the conduction-band quantum well) and the H-layer valence-band quantum well comprises a 5.24-Å-thick In_{0.3}Ga_{0.7}Sb shoulder layer, a 13.87-Å-thick GaSb central layer, and another 5.24-Å-thick In_{0.3}Ga_{0.7}Sb shoulder layer. The two bottom electrical contact layers and the first top electrical contact layer have the same structure as the type-II quantum well absorbing region, and the second top electrical contact layer is GaSb.

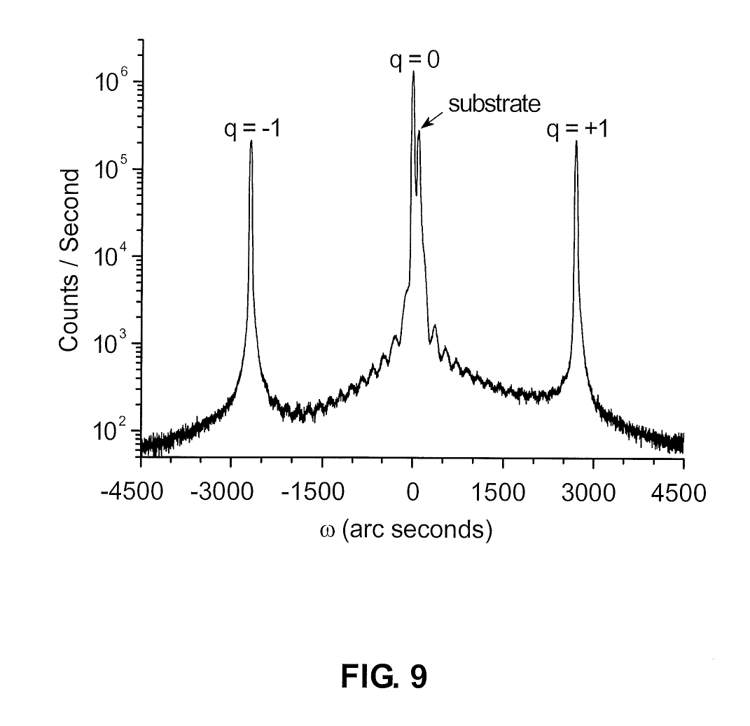

The detector structure containing the H-layer valence-band quantum wells was characterized using high-resolution x-ray diffraction, which is typically used in connection with molecular beam epitaxial growth of strained structures to quantitatively assess the degree of lattice mismatch, to measure the thickness of a superlattice period, and as an overall measure of material quality. FIG. 9 shows the results of the measurement. From the angular separations between adjacent sets of satellite peaks (labeled as q=−1, q=0, and q=+1 in FIG. 9), the thickness of a superlattice period of 68.33 Å is determined. This value is 1.8% larger than the intended superlattice period thickness, which is well within expected tolerances. Also, from the separation between the q=0 satellite peak and the peak corresponding to the GaSb substrate, the mismatch between the superlattice and the substrate is determined to be only −98 parts per million. This is well within the tolerance needed to effectively lattice-match an epitaxial structure to a substrate and demonstrates that the goal of lattice-matching the H-layer valence-band quantum well structure to the substrate was achieved.

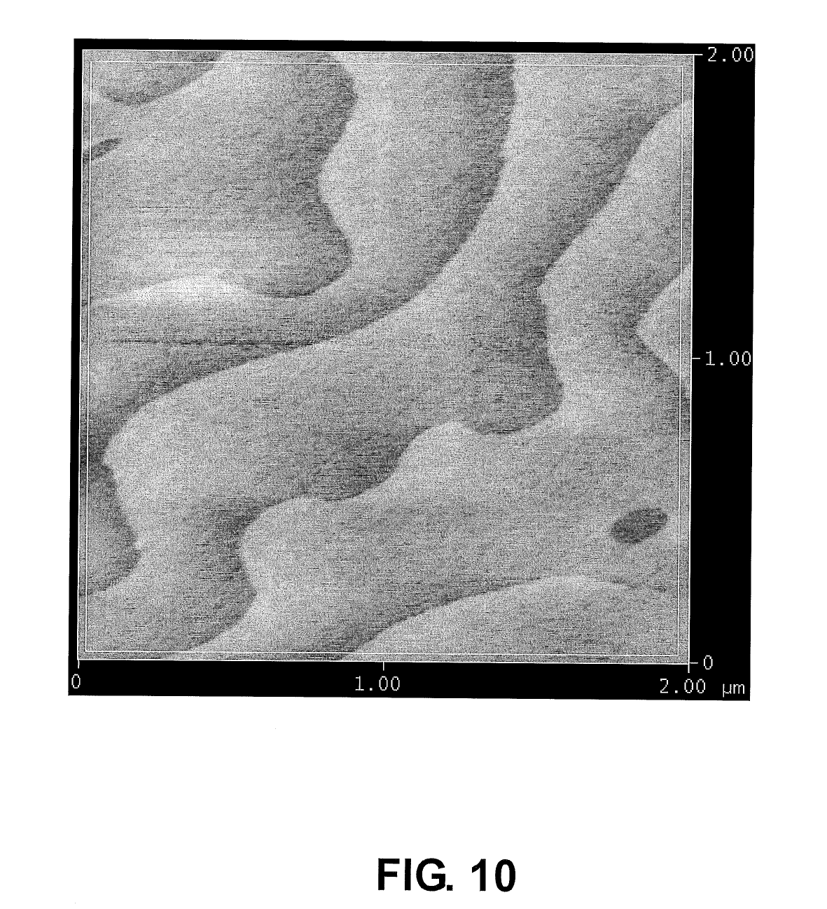

FIG. 10 shows an image of the surface of the type-II infrared detector structure containing the H-layer valence-band quantum wells. The sample area covered by the measurement is 2 μm×2 μm. From the measurement, the root-mean-square roughness of the surface was determined to be 1.11 Å, which is an excellent result and is typical of the best results obtained for type-II infrared detectors that are based on conventional InAs/GaSb type-II absorbing regions. This result demonstrates that using the H-layer valence-band quantum wells in the type-II detector structure produced no apparent adverse effects on the quality of the epitaxial structure.

Detector diodes were fabricated from the epitaxial wafer containing the type-II H-layer valence-band quantum wells using methods that are conventional to those skilled in the art including an inductively coupled plasma dry etch based on BCl₃/Ar chemistry to form individual detector mesa diodes as well as SU-8 photoresist deposited upon the mesa side walls to passivate their surfaces and thereby reduce parasitic surface current pathways.

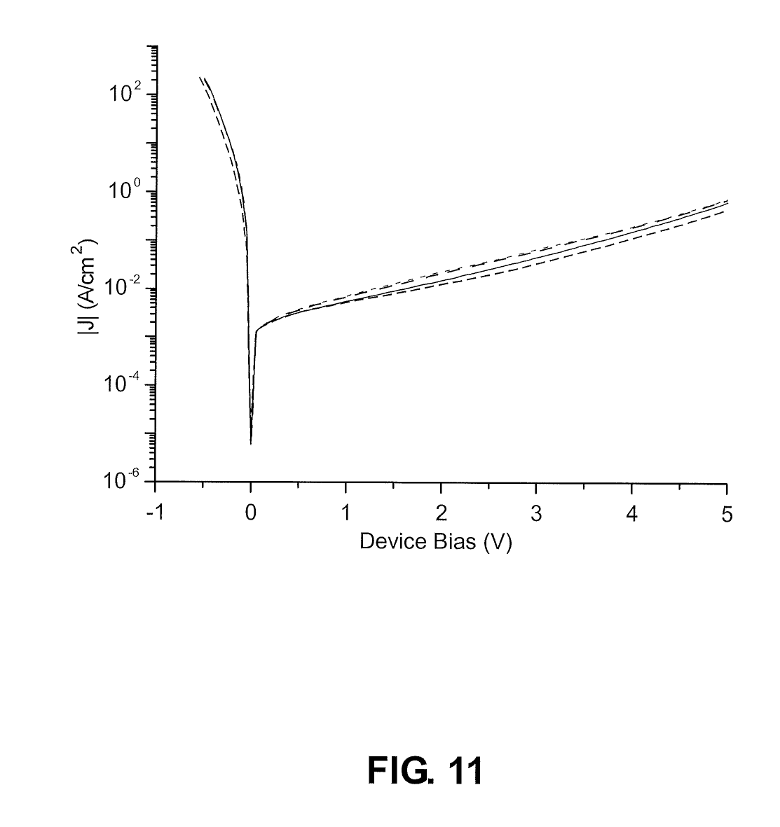

One of the methods used to evaluate the performance of type-II infrared detectors is to measure the dark current of the detector diodes at a temperature at which the detector will be used. FIG. 11 shows a plot of dark-current density as a function of device bias for four detector diodes with 38-μm diameters that were fabricated from the epitaxial wafer containing the type-II H-layer valence-band quantum wells plotted as a function of device bias at a temperature of 78 K. For small values of reverse diode bias, indicated as positive values of bias in FIG. 11, the measured dark-current densities are on the order of 10⁻³ A/cm², which is excellent for diodes with cutoff wavelengths of ˜10 μm that do not contain blocking layers.

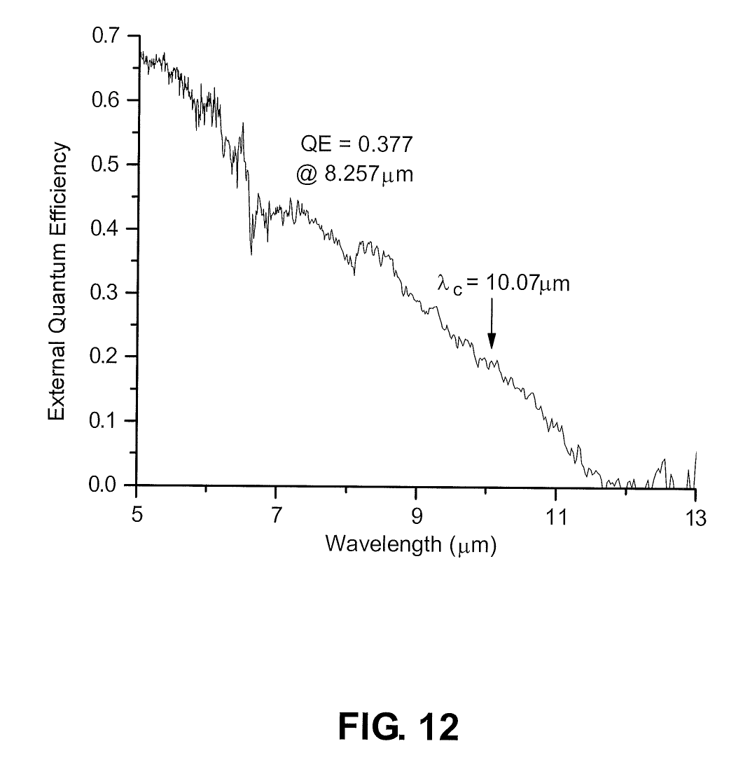

Another method used to evaluate the performance of type-II infrared detectors is to measure the external quantum efficiency of a detector diode at a temperature at which the detector will be used. The external quantum efficiency is the ratio of the number of electron-hole pairs collected at the detector's contacts to the number of photons that are incident on the detector's active area. FIG. 12 shows a plot of the external quantum efficiency as a function of light wavelength for a detector having a 58-μm etched diameter (the illuminated diameter is 30 μm) at a temperature of 78 K with a detector reverse bias of 0.05 V. From the data presented in FIG. 12, a cutoff wavelength λ=10.07 μm is extracted, which is extremely close to the intended design value λ_{c}=10.00 μm. At a wavelength λ˜0.8λ_{c}, the external quantum efficiency is approximately 0.38. This value of external quantum efficiency is not as high as was expected, which is attributed to imperfect design of the contact layers in the detector structure and is not an inherent property of the H-layer valence-band quantum wells. The detector's responsivity, defined as the current produced per unit of optical power incident on the detector's active area, is related to the external quantum efficiency of the detector by R=(hc/eλ)η, where h is Planck's constant, c is the vacuum speed of light, e is the magnitude of the electron charge, λ is the light wavelength, and η is the external quantum efficiency.

A photon detector's detectivity D* is related to the signal-to-noise ratio achieved in a detector with a given incident photon flux, normalized to unit detector area and detection bandwidth. The detectivity is calculated from the measured dark-current density and quantum efficiency results that are shown in FIGS. 11 and 12, respectively.

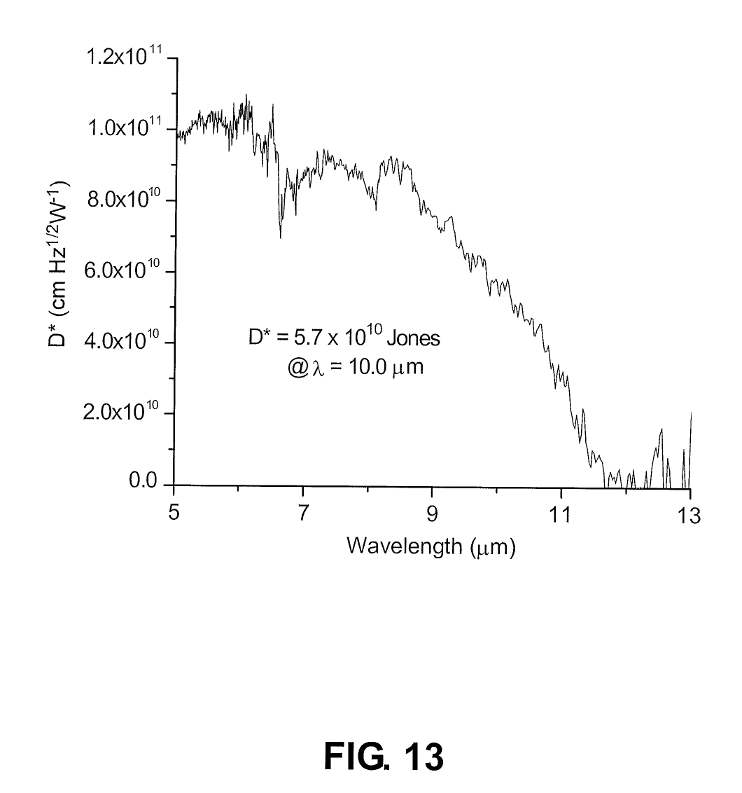

FIG. 13 shows the calculated detectivity D* plotted as a function of wavelength for a detector having a 58-μm etched diameter (the illuminated diameter is 30 μm) at a temperature of 78 K with a detector reverse bias of 0.05 V. At a wavelength of 10 μm, the value of D* is 5.7×10¹⁰ Jones, and at wavelengths around 8 μm, the value of D* is 9×10¹⁰ Jones. Both of these values are excellent for type-II superlattice detectors with similar cutoff wavelengths and without blocking layers.

Whereas particular embodiments of this invention have been described above for purposes of illustration, it will be evident to those skilled in the art that numerous variations of the details of the present invention may be made without departing from the invention as defined in the appended claims.

1. A type-II optoelectronic device including one or more compound valence-band quantum well structures comprising:
a central layer; and
a pair of shoulder layers located on opposite sides of the central layer, wherein each shoulder layer has a valence-band-edge energy larger than a valence-band-edge energy of the central layer.

2. The type-II optoelectronic device of claim 1, wherein at least one of the shoulder layers reduces strain caused by a lattice mismatch between a substrate of the device and other layers of the device.

3. The type-II optoelectronic device of claim 2, wherein the at least one shoulder layer substantially eliminates the lattice mismatch.

4. The type-II optoelectronic device of claim 1, wherein each of the shoulder layers comprises InₓGa₁₋ₓSb or InₓGa₁₋ₓAs_{y}Sb_{1-y}.

5. The type-II optoelectronic device of claim 1, wherein each of the shoulder layers has a thickness of from about 2 to about 15 Å.

6. The type-II optoelectronic device of claim 1, wherein the central layer comprises GaSb, InₓGa₁₋ₓSb or InₓGa₁₋ₓAs_{y}Sb_{1-y}.

7. The type-II optoelectronic device of claim 1, wherein the central layer has a thickness of from about 15 to about 100 Å.

8. The type-II optoelectronic device of claim 1, comprising from 30 to 800 repeating layers of the compound valence-band quantum well structures.

9. The type-II optoelectronic device of claim 8, wherein the repeating layers have a total combined thickness of from about 5,000 to about 50,000 Å.

10. The type-II optoelectronic device of claim 1, wherein each of the compound valence-band quantum well structures comprises at least one conduction-band quantum well layer adjacent to at least one of the shoulder layers forming a type-II heterojunction.

11. The type-II optoelectronic device of claim 10, comprising a pair of the conduction-band quantum well layers on opposite sides of the pair of shoulder layers forming type-II heterojunctions.

12. The type-II optoelectronic device of claim 10, wherein each of the conduction-band quantum well layers comprises InAs or InSbₓAs₁₋ₓ.

13. The type-II optoelectronic device of claim 10, wherein each of the conduction-band quantum well layers has a thickness of from about 20 to about 100 Å.

14. The type-II optoelectronic device of claim 10, comprising multiple repeating layers of the compound valence-band quantum well structures.

15. The type-II optoelectronic device of claim 14, further comprising:
a substrate;
a first contact layer between the substrate and the compound valence-band quantum well structures; and
a second contact layer over the compound valence-band quantum well structures.

16. The type-II optoelectronic device of claim 15, wherein the device is an infrared detector.

17. The type-II optoelectronic device of claim 15, wherein the device is an infrared optical modulator.

18. The type-II optoelectronic device of claim 15, further comprising blocking layers between each of the first and second contact layers and the compound valence-band quantum well structures.

19. The type-II optoelectronic device of claim 18, wherein each of the blocking layers comprises InAs, GaSb or AlSb and has a thickness of from about 1,000 to about 5,000 Å.

20. The type-II optoelectronic device of claim 18, wherein the device is an infrared detector.

21. The type-II optoelectronic device of claim 14, further comprising injection region layers between the multiple repeating layers.

22. The type-II optoelectronic device of claim 21, wherein each of the injection region layers comprises InAs, AlSb or GaSb and has a thickness of from about 150 to about 600 Å.

23. The type-II optoelectronic device of claim 21, wherein the device is an interband cascade laser.

24. The type-II optoelectronic device of claim 14, further comprising barrier layers between the multiple repeating layers.

25. The type-II optoelectronic device of claim 24, wherein each of the barrier layers comprises AlSb, AlₓGa₁₋ₓSb or AlₓGa₁₋ₓAs_{y}Sb_{1-y} and has a thickness of from about 20 to about 100 Å.

26. The type-II optoelectronic device of claim 24, wherein the device is a W diode laser.

27. The type-II optoelectronic device of claim 24, wherein the device is an optically pumped laser.

28. The type-II optoelectronic device of claim 1, wherein the device is selected from the group consisting of infrared detectors, infrared optical modulators, interband cascade lasers, diode lasers and optically pumped lasers.

29. A type-II optoelectronic device including one or more compound valence-band quantum well structures comprising:
a central layer; and
a pair of shoulder layers located on opposite sides of the central layer, wherein at least one of the shoulder layers reduces strain caused by a lattice mismatch between a substrate of the device and other layers of the device.

30. The type-II optoelectronic device of claim 29, wherein the at least one shoulder layer substantially eliminates the lattice mismatch.

31. The type-II optoelectronic device of claim 29, wherein each shoulder layer has a valence-band-edge energy larger than a valence-band-edge energy of the central layer.
